(19) United States
(12) Patent Application Publication
(10) Pub. No.: US 2005/0218781 A1
(43) Pub. Date: Oct. 6, 2005

(54) Triple wavelengths light emitting diode

(76) Inventor: Hsing Chen, Kukou Township (TW)

Correspondence Address: PRO-TECHTOR INTERNATIONAL, 20775 Norada Court, Saratoga, CA, 95070-3018, US

(21) Appl. No.: 11/138,092

(22) Filed: May 27, 2005

Related U.S. Application Data
(63) Continuation-in-part of application No. 10/238,169, filed on Sep. 9, 2002, now abandoned.

(51) Int. Cl. H01L 29/22

(52) U.S. Cl. 313/467

(57) ABSTRACT

A triple wavelengths light emitting diode includes a blue LED chip whose wavelength is ranged between 430 nm and 480 nm. A red and green mixed phosphor is coated on the blue LED chip. Thus, the red and green mixed phosphor may be excited by the blue LED chip to produce a triple wavelengths light emitting diode.

This is a continuation in—part application of applicant's U.S. patent application Ser. No. 10,238,169, filed on Sep. 09, 2002.

### BACKRROUND OF THE INVENTION

1. Field of the Invention

The present invention relates to a triple wavelengths light emitting diode, and more particularly to a triple wavelengths light emitting diode, wherein the red and green mixed phosphor that may be excited by the blue LED chip is made of an oxide, so that the red and green mixed phosphor has a greeter stability and a longer lifetime.

2. Description of the Related Art

The conventional method for manufacturing a white LED adopts a single LED chip to produce the white light. The surface of the single LED chip is coated with a layer of phosphor, so that the light produced by the single LED chip may excite the phosphor, so as to produce light with different wavelengths. The lights with different wavelengths may mix with the light produced by the single LED chip, so as to produce the white light.

A first conventional method for manufacturing a white LED adopts a blue LED chip and YAG yellow phosphor, so that the yellow color and the blue color may be complimentary with each other, thereby producing the white LED with two wavelengths. The above-said first conventional method for manufacturing a white LED is disclosed in U.S. Pat. No. 5,998,925 to Nichia Corporation. FIG. 1 is an emission spectrum of the first conventional method for manufacturing two wavelengths white LED disclosed by the Nichia Corporation.

However, in the first conventional method for manufacturing a white LED, the white LED only has blue light and yellow light with two wavelengths. Thus, the white LED is only available for indication, and cannot be used for illumination or the full color LCD backlight. In addition, the amount of the YAG yellow phosphor cannot be controlled exactly, so that the white LED easily produces bluish or yellowish.

### SUMMARY OF THE INVENTION

The present invention has arisen to mitigate and/or obviate the disadvantage of the conventional methods for manufacturing a triple wavelengths light emitting diode.

The primary objective of the present invention is to provide a triple wavelengths light emitting diode, wherein the blue LED chip (the wavelength is ranged between 430 nm and 480 nm) may be used to excite the phosphor mixed with red and green colors, so as to produce triple wavelengths light emitting diode.

According to the present invention, the triple wavelength light emitting diode includes a blue LED chip (the range of wavelength is between 430 nm and 480 nm) to excite the phosphor mixed with red and green colors, so as to produce red and green lights that may be mixed with the blue light of the blue LED chip, thereby producing the three wavelengths rays.

The reason of adopting the blue LED chip (the wavelength is ranged between 430 nm and 480 nm) is in that, the light emitting efficiency and power of the blue LED chip are greater than that of the ultraviolet LED. In addition, the phosphor mixed with red and green colors that may be excited by the blue LED chip is made of an oxide, so that the phosphor mixed with red and green colors has a greater stability and a longer lifetime.

The components of the phosphor mixed with red and green colors, which may be excited by the blue LED chip (the wavelength is ranged between 430 nm and 480 nm) are listed as follows.

The component of the red phosphor is as follows:
Li₂TiO₃: Mn; or
LiAlO₂: Mn; or
6MgO.As₂O₅: Mn⁴⁺; or
3.5MgO.0.5MgF₂.GeO₂: Mn⁴⁺

The component of the green phosphor is as follows:
Y₃(Ga_{X}Al_{1-X})₅O₁₂: Ce(0<x<1); or
La₂O₃.11Al₂O₃: Mn; or
Ca₈Mg(SiO₄)₄Cl₂: Eu, Mn.

Recently, the white LED adopts the manufacturing method of the Nichia corporation, that is, adopts a blue LED chip and YAG yellow phosphor. The chemical component of the YAG yellow phosphor is (YGd)₃Al₅O₁₂: Ce, with a wavelength ranged between 550 nm and 560 nm.

In comparison, the component of the green phosphor of the present invention is Y₃(Ga_{X}AL_{1-X})₅O₁₂: Ce(0<x<1), with a light emitting peak wavelength ranged between 515 nm and 520 nm. In addition, the component of the other green phosphor of the present invention is La₂O₃.11Al₂O₃: Mn or Ca₈Mg(SiO₄)₄Cl₂: Eu, Mn, and the component of the red phosphor of the present invention is Li₂TiO₃: Mn, or LiAlO₂: Mn, or 6MgO.As₂O₅: Mn⁴⁺, or 3.5MgO.0.5MgF₂.GeO₂: Mn⁴⁺. Thus, the green phosphor and the red phosphor of the present invention are mixed according to a proper proportion, and may be directly or indirectly coated on the blue LED chip, the mixed phosphor are excited by the blue LED chip, thereby obtaining the white LED with three wavelengths. In addition, the green phosphor and the red phosphor of the present invention may be mixed according to various proportions, thereby forming an LED with a middle color, such as the pink color, the bluish white color or the like.

In accordance with one aspect of the present invention includes a blue LED chip (the wavelength is ranged between 430 nm and 480 nm), and a red and green mixed phosphor that may be excited by the blue LED chip, wherein:

The red and green mixed phosphor absorbs a part of blue rays emitted from the blue LED chip, to excite red rays and green rays having wavelengths different from that of the absorbed blue rays, the excited red rays and green rays are then mixed with the blue rays emitted from the blue LED chip, thereby producing a triple wavelengths white LED;

The red and green mixed phosphor includes a red phosphor that at least contains: Li₂TiO₃: Mn; or
LiAlO₂: Mn; or
6MgO.As₂O₅: Mn⁴⁺; or
3.5MgO.0.5MgF₂.GeO₂: Mn⁴⁺; and
the red and green mixed phosphor includes a green phosphor that at least contains: Y₃(Ga_{X}Al_{1-X})₅O₁₂: Ce(0<x<1); or
La₂O₃.11Al₂O₃: Mn; or
Ca₈Mg(SiO₄)₄Cl₂:Eu, Mn.

Preferably, the red phosphor of the red and green mixed phosphor is Li₂TiO₃: Mn when a light emitting peak wavelength is about 659 nm, is LiAlO₂: Mn when a light emitting peak wavelength is about 670 nm, is 6MgO.As₂O₅: Mn⁴⁺ when a light emitting peak wavelength is about 650 nm, or is 3.5MgO.0.5MgF₂.GeO₂: Mn⁴⁺ when a light emitting peak wavelength is about 650 nm.

Preferably, the green phosphor of the red and green mixed phosphor is La₂O₃.11Al₂O₃: Mn when a light emitting peak wavelength is about 520 nm, is Y₃(Ga_{X}Al_{1-X})₅O₁₂: Ce(0<x<1) when a light emitting peak wavelength is about 516 nm, or is Ca₈Mg(SiO₄)₄Cl₂: Eu, Mn when a light emitting peak wavelength is about 515 nm.

Preferably, the green phosphor and the red phosphor may be mixed according to various proportions, thereby forming an LED with a middle color, such as a pink color or a bluish white color.
Ca₈Mg(SiO₄)₄Cl₂:Eu, Mn.

Preferably, the red phosphor of the red and green mixed phosphor is Li₂TiO₃: Mn when a light emitting peak wavelength is about 659 nm, is LiAlO₂: Mn when a light emitting peak wavelength is about 670 nm, is 6MgO.As₂O₅: Mn⁴⁺ when a light emitting peak wavelength is about 650 nm, or is 3.5MgO.0.5MgF₂.GeO₂: Mn⁴⁺ when a light emitting peak wavelength is about 650 nm.

Preferably, the green phosphor of the red and green mixed phosphor is La₂O₃.11Al₂O₃: Mn when a light emitting peak wavelength is about 520 nm, is Y₃(Ga_{X}Al_{1-X})₅O₁₂: Ce(0<x<1) when a light emitting peak wavelength is about 516 nm, or is Ca₈Mg(SiO₄)₄Cl₂: Eu, Mn when a light emitting peak wavelength is about 515 nm.

Preferably, the green phosphor and the red phosphor may be mixed according to various proportions, thereby forming an LED with a middle color, such as a pink color or a bluish white color.

Preferably, the blue LED chip has an INGaN type, a SiC type on a ZnSe Type.

Further benefits and advantages of the present invention will become apparent after a careful reading of the detailed description with appropriate reference to the accompanying drawings.

### BRIEF DESCRIPTION OF THE DRAWING

FIG. 1 is an emission spectrum of a conventional method for manufacture two wavelengths white LED disclosed by the Nichia Corporation.

FIG. 2 is a plan cross-sectional structural view of a package method of a white light lamp type LED in accordance with the preferred embodiment of the present invention.

FIG. 3 is a plan cross-sectional structural view of a package method of a light emitting diode SMD (surface mount diode) type LED in accordance with the preferred embodiment of the present invention.

FIG. 4 is a graph of the excitation spectrum and the emission spectrum of the green phosphor of La₂O₃.11Al₂O₃: Mn in the method for manufacturing a triple wavelengths light emitting diode in accordance with the preferred embodiment of the present invention.

FIG. 5 is a graph of the excitation spectrum of the green phosphor of Y₃(Ga_{X}Al_{1-X})₅O₁₂: Ce(0<x<1) in the method for manufacturing a triple wavelengths light emitting diode in accordance with the preferred embodiment of the present invention.

FIG. 6 is a graph of the emission spectrum of the green phosphor of Y₃(Ga_{X}Al_{1-X})₅O₁₂: Ce(0<x<1) in the method for manufacturing a triple wavelengths light emitting diode in accordance with the preferred embodiment of the present invention.

FIG. 7 is a graph of the excitation spectrum of the green phosphor of Ca₈Mg(SiO₄)₄Cl₂: Eu, Mn in the method for manufacturing a triple wavelengths light emitting diode in accordance with the preferred embodiment of the present invention.

FIG. 8 is a graph of the emission spectrum of the green phosphor of Ca₈Mg(SiO₄)₄Cl₂: Eu, Mn in the method for manufacturing a triple wavelengths light emitting diode in accordance with the preferred embodiment of the present invention.

FIG. 9 is a graph of the excitation spectrum of the red phosphor of Li₂TiO₃: Mn in the method for manufacturing a triple wavelengths light emitting diode in accordance with the preferred embodiment of the present invention.

FIG. 10 is a graph of the emission spectrum of the red phosphor of Li₂TiO₃: Mn in the method for manufacturing a triple wavelengths light emitting diode in accordance with the preferred embodiment of the present invention.

FIG. 11 is a graph of the excitation spectrum of the red phosphor of LiAlO₂: Mn in the method for manufacturing a triple wavelengths light emitting diode in accordance with the preferred embodiment of the present invention.

FIG. 12 is a graph of the emission spectrum of the red phosphor of LiAlO₂: Mn in the method for manufacturing a triple wavelengths light emitting diode in accordance with the preferred embodiment of the present invention.

FIG. 13 is a graph of the excitation spectrum and the emission spectrum of the red phosphor of 6MgO.As₂O₅: Mn⁴⁺ in the method for manufacturing a triple wavelengths light emitting diode in accordance with the preferred embodiment of the present invention.

FIG. 14 is a graph of the excitation spectrum and the emission spectrum of the red phosphor of 3.5MgO.0.5MgF₂.GeO₂: Mn⁴⁺ in the method for manufacturing a triple wavelengths light emitting diode in accordance with the preferred embodiment of the present invention.

FIG. 15 is a graph of the emission spectrum of the method for manufacturing a triple wavelengths light emitting diode in accordance with a preferred embodiment of the present invention.

FIG. 16 is a graph of the spectrum of the method for manufacturing a triple wavelengths light emitting diode in accordance with another preferred embodiment of the present invention.

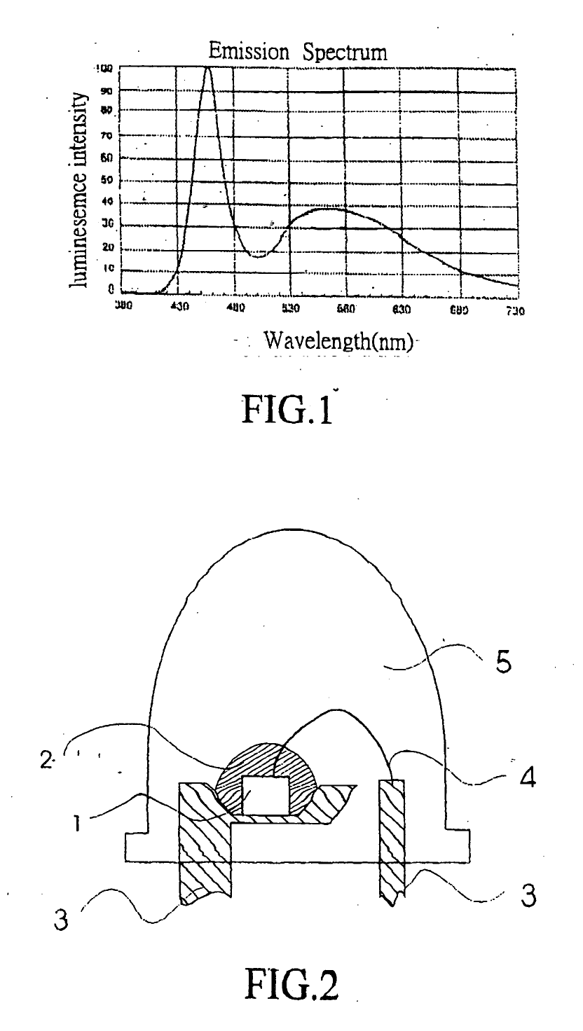

### DETAUKED DESCRIPTION OF THE INVENTION

In accordance with the present invention, the red and green mixed phosphor 2 may be excited by the blue LED chip (the wavelength is ranged between 430 nm and 480 nm).

The component of the red phosphor of the present invention is as follows:
Li₂TiO₃: Mn; or
LiAlO₂: Mn; or
6MgO.As₂O₅: Mn⁴⁺; or
3.5MgO.0.5MgF₂.GeO₂: Mn⁴⁺.

The component of the green phosphor of the present invention is as follows:
Y₃(Ga_{X}Al_{1-X})₅O₁₂: Ce(0<x<1); or
La₂O₃.11Al₂O₃: Mn; or
Ca₈Mg(SiO₄)₄Cl₂: Eu, Mn.

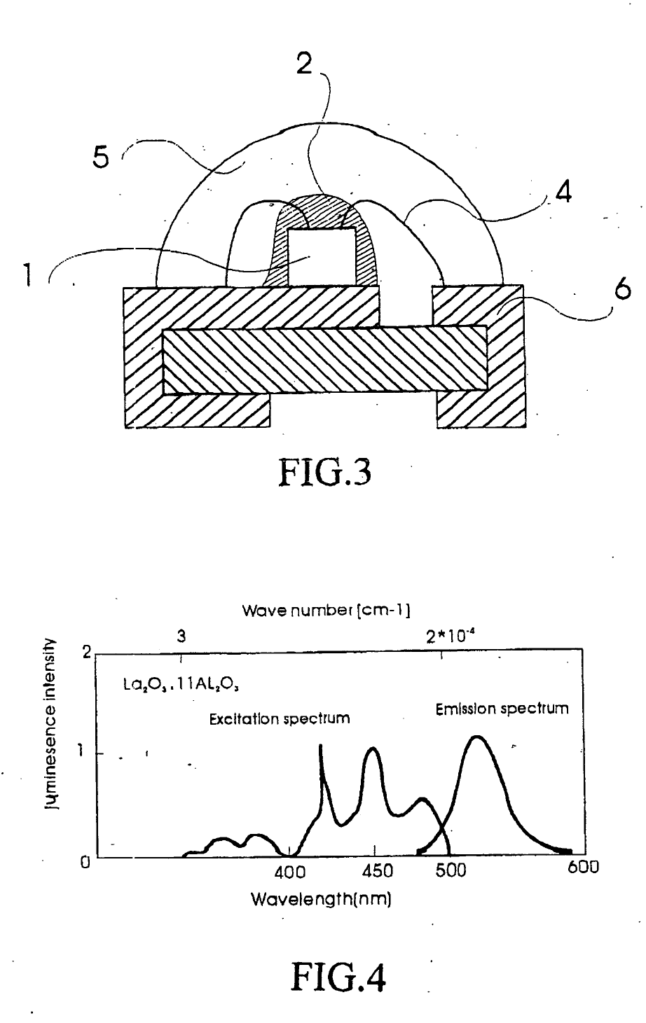

Referring to the drawings and initially to FIGS. 2 and 3, a method for manufacturing a triple wavelengths light emitting diode in accordance with an embodiment of the present invention is illustrated, wherein FIG. 2 is a plan cross-sectional structural view of a package method of a white light lamp type LED in accordance with the preferred embodiment of the present invention, and FIG. 3 is a plan cross-sectional structural view of a package method of a white light SMD (surface mount diode) type LED in accordance with the preferred embodiment of the present invention.

First of all, a red phosphor Li₂TiO₃: Mn and a green phosphor Ca₈Mg(SiO₄)₄Cl₂: Eu, Mn are mixed in a proper proportion to form the red and green mixed phosphor 2 which is mixed with a transparent resin 5 in a proper proportion to form a gum (such as epoxy) of the red and green mixed phosphor 2. A blue LED chip 1 is fixed on a lead frame 3 as shown in FIG. 2 or a package substrate 6 as shown in FIG. 3, and a conductive wire 4 is connected between the blue LED chip 1 and the lead frame 3 or the package substrate 6. Then, the gum of the red and green mixed phosphor 2 is directly or indirectly coated on the blue LED chip 1 in a coating or printing manner, thereby packaging the gum of the red and green mixed phosphor 2 and the blue LED chip 1 into a lamp type LED or a SMD type LED. The blue rays emitted from the blue LED chip 1 may excite the red and green mixed phosphor 2, so as to produce red and green rays which may be mixed with the blue rays emitted from the blue LED chip 1, so as to produce a triple wavelengths white LED with the mixed red, green and blue rays.

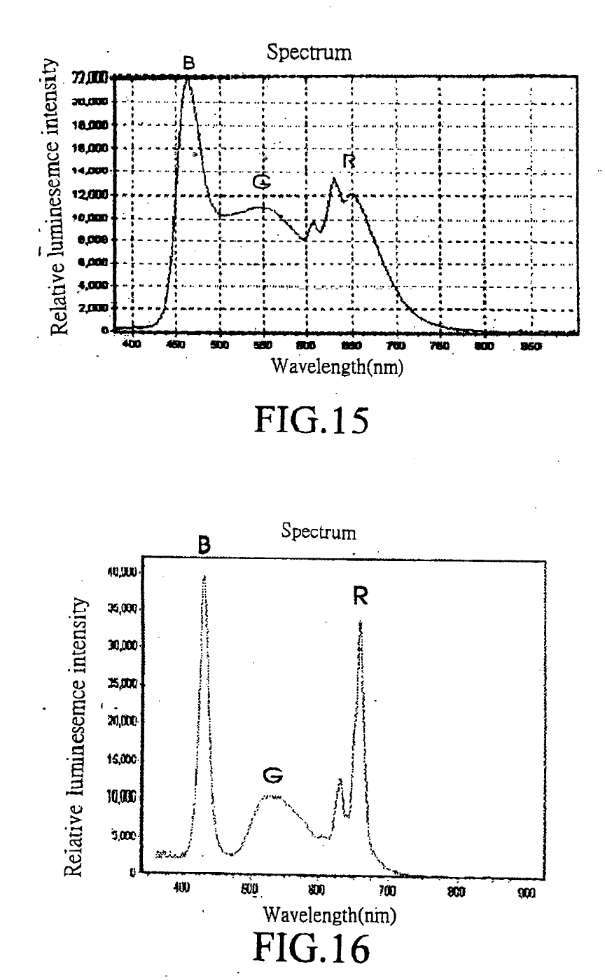

Thus, the emission spectrum of the produced triple wavelengths white LED is shown in FIG. 15. FIG. 16 is a graph of the emission spectrum of the method for manufacturing a triple wavelengths light emitting diode in accordance with another preferred embodiment of the present invention.

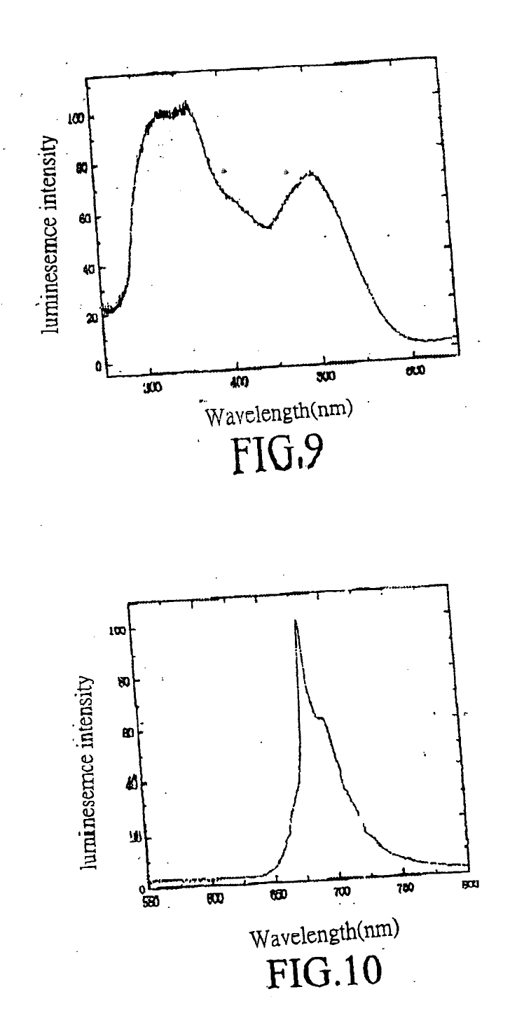

In addition, the excitation spectrum and the emission spectrum of the red phosphor Li₂TiO₃: Mn are shown in FIG. 9 and FIG. 10.

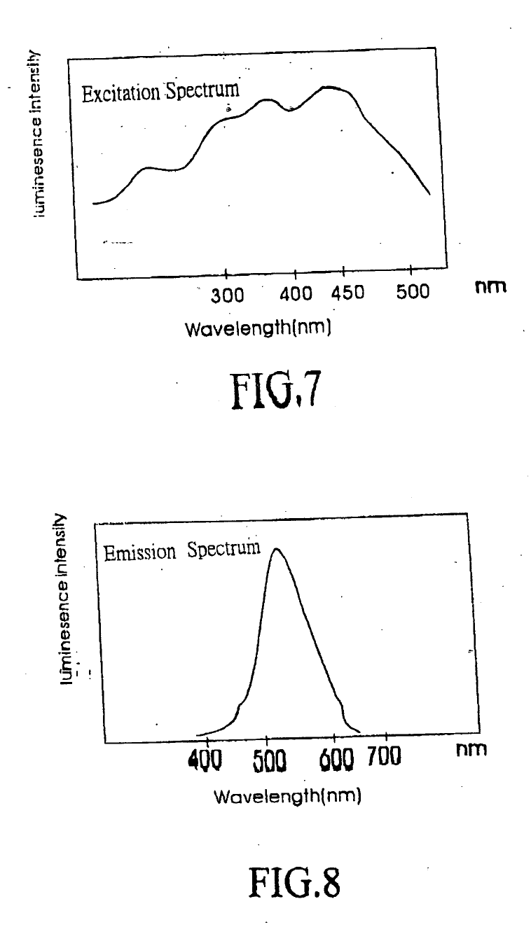

In addition, the excitation spectrum and the emission spectrum of the green phosphor Ca₈Mg(SiO₄)₄Cl₂: Eu, Mn are shown in FIG. 7 and FIG. 8.

The other phosphors of the present invention are available for the blue LED chip 1.

For example, the excitation spectrum and the emission spectrum of the green phosphor La₂O₃.11Al₂O₃: Mn are shown in FIG. 4.

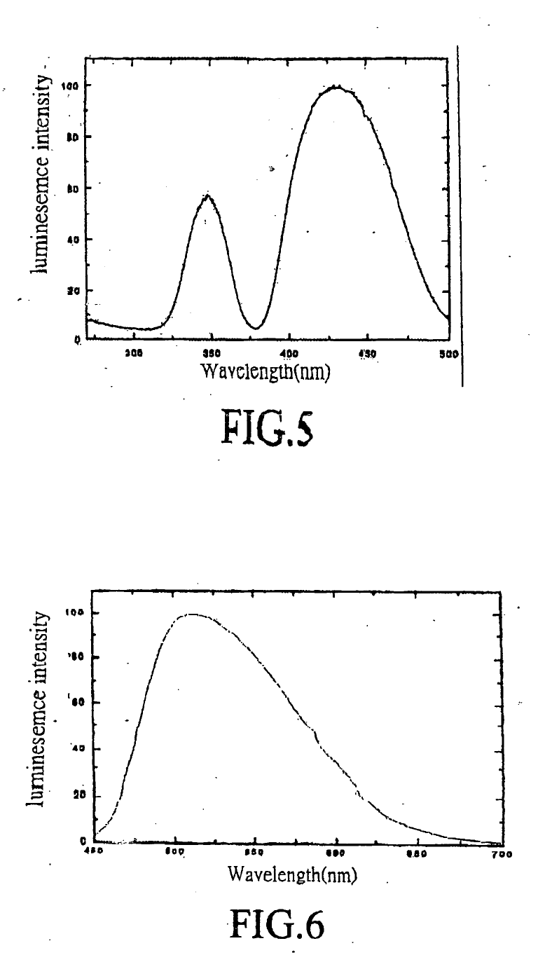

In addition, the excitation spectrum and the emission spectrum of the green phosphor Y₃(Ga_{X}Al_{1-X})₅O₁₂: Ce(0<x<1) are shown in FIG. 5 and FIG. 6.

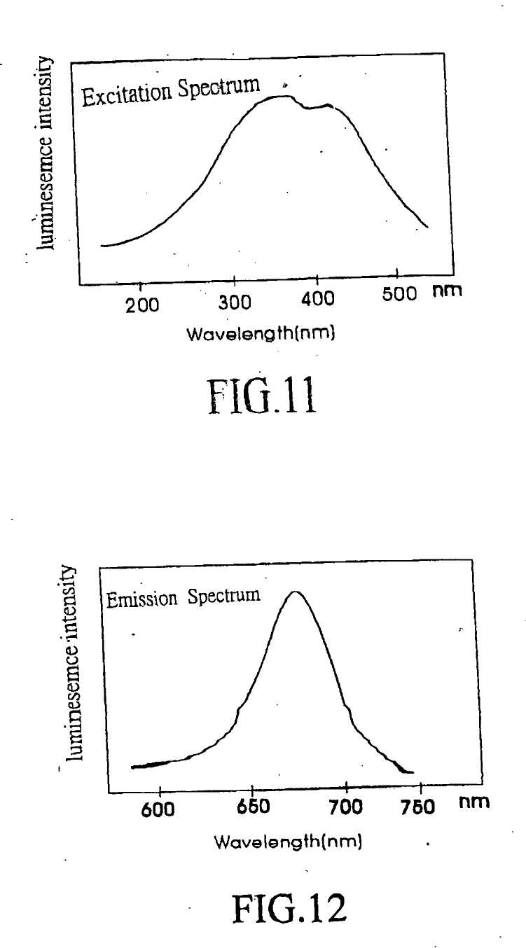

In addition, the excitation spectrum and the emission spectrum of the red phosphor LiAlO₂: Mn are shown in FIG. 11 and FIG. 12.

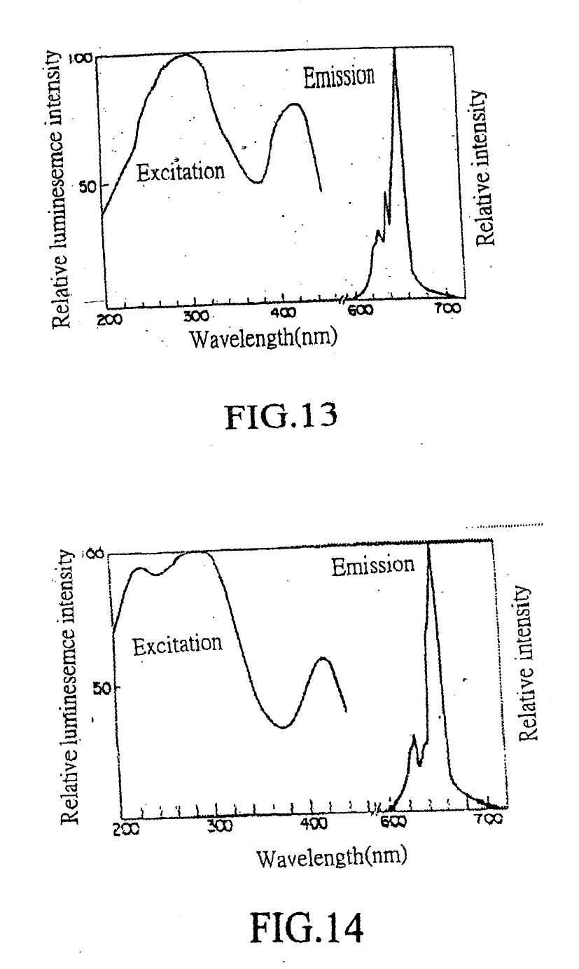

In addition, the excitation spectrum and the emission spectrum of the red phosphor 6MgO.As₂O₅: Mn⁴⁺ are shown in FIG. 13.

In addition, the excitation spectrum and the emission spectrum of the red phosphor 3.5MgO.0.5MgF₂.GeO₂: Mn⁴⁺ are shown in FIG. 14.

The excitation spectrum and the emission spectrum of the phosphors of the present invention have some difference. Thus, the blue LED chip 1 may choose its available phosphor. For example, when the blue LED chip 1 has the wavelength of 430 nm, the red phosphor may adopt 6MgO.As₂O₅: Mn⁴⁺ or 3.5MgO.0.5MgF₂.GeO₂: Mn⁴⁺, and the green phosphor may adopt Y₃(Ga_{X}Al_{1-X})₅O₁₂: Ce(0<x<1) or Ca₈Mg(SiO₄)₄Cl₂: Eu, Mn.

In comparison, the Nichia corporation adopts a blue LED chip and YAG yellow phosphor. The chemical component of the YAG yellow phosphor is (Y_{X}Gd_{1-X})₃Al₅O₁₂: Ce. Thus, the blue rays of the blue LED chip may excite the YAG yellow phosphor to produce yellow rays that may be mixed with the blue rays of the blue LED chip, so that the yellow color and the blue color may be complimentary with each other, thereby producing the white LED with two wavelengths.

On the other hand, the phosphor used in the present invention is different from that of the Nichia corporation, and the making manner of the present invention is different from that of the Nichia corporation. In addition, the phosphor used in the present invention may be used to make the white LED with three wavelengths, and the green phosphor and the red phosphor of the present invention may also be mixed according to various proportions, thereby forming an LED with a middle color, such as the pink color, the bluish white color or the like.

Accordingly, according to the method for manufacturing a triple wavelengths light emitting diode of the present invention, the blue LED chip may excite the red and green mixed phosphor, so as to produce a triple wavelengths light emitting diode with the mixed red, green, and blue rays. The blue LED chip has a greater brightness, so that the triple wavelengths made by blue LED chip exciting the red and green mixed phosphor has a pure color and has a better brightness.

Wherein the percentage of the red phosphor is 60-85 percent, the percentage of the green phosphor is 15-40 percent to produce triple wavelengths white light emitting diode. Wherein the percentage of the red phosphor is 85-95 percent, the percentage of the green phosphor is 5-15 percent to produce triple wavelengths pink light emitting diode.

Wherein the percentage of the red phosphor is 20-60 percent, the percentage of the green phosphor is 40-80 percent to produce triple wavelengths green light emitting diode.

In conclusion, the method of the present invention obtains a red and green mixed phosphor that is available for the blue LED chip (the wavelength is ranged between 430 nm to 480 nm). In addition, the red and green mixed phosphor that may be excited by the blue LED chip is made of an oxide, so that the red and green mixed phosphor has a greater stability and longer lifetime. Thus, the triple wavelengths white LED of the present is available for purposes of indication, illustration, mono color or full color liquid chip backlight of the like.

Although the invention has been explained in relation to its preferred embodiment above, it is to be understood that many other possible modifications and variation can be made without departing from the scope of the present invention, it is therefore, contemplated that the appended claim or claims will cover such modifications and variations that fall within the true scope of the invention.

1. A triple wavelengths light emitting diode, comprising:
a blue LED chip with a wavelength between 430 nm and 480 nm;
a red phosphor and green phosphor mixed in a proper proportion to form a red and green mixed phosphor, which is coated on the blue LED chip capable of absorbing blue rays emitted from the blue LED, and emitting red wavelength rays and green wavelength rays, mixing the blue wavelength rays, red wavelength rays, and green wavelength rays to produce the triple wavelengths rays;
The red and green mixed phosphor includes a red phosphor that contains as least a component of Li₂TiO₃: Mn; or LiALO₂Mn; or 6MgO.As₂O₅: Mn⁴⁺; or 3.5MgO.0.5MgF₂.GeO₂: Mn⁴⁺; and
The red and green mixed phosphor includes a green phosphor that contains as least a component of Y₃(Ga_{X}AL_{1-X})₅O₁₂: Ce(0<x<1>; or La₂O₃.11Al₂O₃: Mn; or Ca₈Mg(SiO₄)₄Cl₂: Eu, Mn.

2. The triple wavelengths light emitting diode according to claim 1, wherein the red phosphor and the green phosphor are mixed in a proper proportion to form a red and green phosphor, which is mixed with a transparent resin in a proper proportion to form a gum of the red and green mixed phosphor.

3. The triple wavelengths light emitting diode according to claim 1, wherein the percentage of the red phosphor is 60-85 percent, the percentage of the green phosphor is 15-40 percent to produce triple wavelengths white light emitting diode.

4. The triple wavelengths light emitting diode according to claim 3, wherein the percentage of the red phosphor is 70 percent, the percentage of the green phosphor is 30 percent to produce triple wavelengths white light emitting diode.

5. The triple wavelengths light emitting diode according to claim 1, wherein the percentage of the red phosphor is 85-95 percent, the percentage of the green phosphor is 5-15 percent to produce triple wavelengths pink light emitting diode.

6. The triple wavelengths light emitting diode according to claim 1, wherein the percentage of the red phosphor is 20-60 percent, the percentage of the green phosphor is 40-80 percent to produce triple wavelengths green light emitting diode.
